(19) United States
(12) Patent Application Publication
(10) Pub. No.: US 2026/0193533 A1
(43) Pub. Date: Jul. 9, 2026

(54) QUANTUM DOTS, METHOD FOR PRODUCING SAME, AND ELECTRONIC DEVICE

(71) Applicant: DUK SAN NEOLUX CO., LTD., Cheonan-si, Chungcheongnam-do (KR)

(72) Inventors: Han Byule LIM, Cheonan-si (KR); Chang Min LEE, Cheonan-si (KR); Jong Moon SHIN, Cheonan-si (KR); Kyung Soo KIM, Cheonan-si (KR)

(21) Appl. No.: 19/129,068

(22) PCT Filed: Oct. 20, 2023
(86) PCT No.: PCT/KR2023/016341

§ 371 Date: May 12, 2025

(30) Foreign Application Priority Data
Nov. 17, 2022 (KR) 10-2022-0154931

(51) Int. Cl. C09K 11/56; B82Y 20/00; B82Y 30/00; B82Y 40/00; C09K 11/58; C09K 11/62; H10H 20/851; H10H 29/851

(52) U.S. Cl. CPC C09K 11/56; B82Y 20/00; B82Y 30/00; B82Y 40/00; C09K 11/58; C09K 11/62; H10H 20/8512; H10H 29/8512

(57) ABSTRACT

The present embodiments may provide quantum dots, a method for producing same, and an electronic device, each quantum dot comprising: a core comprising Ag, In, Ga and S; and a first shell, disposed on the core, comprising at least one Group I element, at least one Group III element, and at least one Group VI element, the molar ratio of Group III element to Group I element+Group III+VI element being 1:10 to 1:2.

### TECHNICAL FIELD

The present disclosure relates to a quantum dot, a method of manufacturing the quantum dot, and an electronic device.

### BACKGROUND ART

Quantum dots (QDs) are semiconductor particles having a size of a few nanometers and having superior optical and electric properties that differ from bulk semiconductor materials. For example, quantum dots have characteristics of emitting light through photoluminescence (PL), in which light is generated as electrons drop down from the conduction band to the valence band, or electroluminescence (EL), in which light is generated by external charges. Even in the case in which the quantum dots are formed of the same material, the color of emission light may vary depending on the size of the quantum dots. Due to these characteristics, quantum dots are attracting attention for use in next-generation light-emitting diodes (LEDs), biosensors, lasers, solar cell nanomaterials, and the like.

Meanwhile, the core surface of the quantum dot easily forms chemical bonds when approached by other atoms or molecules, which may cause surface defects and reduce luminescence efficiency. Accordingly, in order to prevent a decrease in luminescence efficiency of the core, the quantum dot with core/shell structure in which the shell is formed on the core surface has been developed.

However, despite the introduction of the shell, there is a problem in that the luminescence efficiency of quantum dots is limited to a certain level due to the increase in wavelength and Full Width at Half Maximum.

### DISCLOSURE

### Technical Problem

Embodiments of the present disclosure may provide a quantum dot with decreased wavelength and Full Width at Half Maximum of the quantum dot, a method of manufacturing the quantum dot, and an electronic device.

Embodiments of the present disclosure may provide a quantum dot with superior luminescence efficiency, a method of manufacturing the quantum dot, and an electronic device.

### Technical Solution

In an aspect, embodiments of the present disclosure may provide a quantum dot comprising a core and a first shell.

A core may include silver (Ag), indium (In), gallium (Ga) and sulfur(S). A first shell may be disposed on the core. The first shell may include at least one Group I element, at least one Group III element and at least one Group VI element, wherein the first shell may have a molar ratio of the Group III element and the Group I element+the Group III element+the Group VI element of 1:10 to 1:2.

Embodiments of the present disclosure may provide a quantum dot comprising a core and a first shell, along with a second shell.

A second shell may be disposed on the first shell. The second shell may include at least one Group III element and at least one Group VI element, wherein the second shell may have a molar ratio of the Group III element and the Group III element+the Group VI element of 1:10 to 1:2.

A first shell may have a molar ratio of the Group III element and the Group I element+the Group III element+the Group VI element of 3:10 to 1:2.

A second shell may have a molar ratio of the Group III element and the Group III element+the Group VI element of 3:10 to 1:2.

A quantum dot may have a luminescence efficiency of a core and a first shell of 68.2% to 77.2%. The luminescence efficiency of a core, a first shell and a second shell may have 85.3% to 95.4%.

At least one Group I element included in the first shell may include one or more selected from Li, Na, K, Rb, Cs, Cu, Ag, and Au.

At least one Group III element included in the first shell and the second shell may include one or more selected from Al, Ga, In and Tl. The Group III element included in the first shell and the Group III element included in the second shell may be the same of different.

At least one Group VI element included in the first shell and the second shell may include one or more selected from S, Se and Te. The Group VI element included in the first shell and the Group VI element included in the second shell may be the same of different.

A first shell may include one of AgAlS, AgAlSe, AgAlTe, AgGaS, AgGaSe, AgGaTe, AgInS, AgInSe, AgInTe, AgTiS, AgTiSe, AgTiTe, CuAlS, CuAlSe, CuAlTe, CuGaS, CuGaSe, CuGaTe, CuInS, CuInSe, CuInTe, CuTiS, CuTiSe, CuTiTe, AuAlS, AuAlSe, AuAlTe, AuGaS, AuGaSe, AuGaTe, AuInS, AuInSe, AuInTe, AuTiS, AuTiSe, and AuTiTe.

A second shell may include one of AlS, AlSe, AlTe, GaS, GaSe, GaTe, InS, InSe, InTe, TiS, TiSe, and TiTe.

In another aspect, embodiments of the present disclosure may provide a method of manufacturing a quantum dot.

A method of manufacturing a quantum dot may comprise a core preparation step and a first shell preparation step.

A core preparation step may be a step of preparing a core. The core preparation step may be the step of preparing the core by injecting and reacting a silver precursor, an indium precursor, a gallium precursor, a sulfur precursor and a solvent in a first reactor.

A first shell preparation step may be a step of preparing a first shell by injecting and reacting the prepared core in a first reactor containing at least one of a Group I precursor including a Group I element and a Group III precursor including a Group III element, and a Group VI precursor including a Group VI element, wherein the first shell may have a molar ratio of the Group III element and the Group I element+the Group III element+the Group VI element of 1:10 to 1:2.

A method of manufacturing a quantum dot may comprise a core preparation step and a first shell preparation step, along with a second shell preparation step.

A second shell preparation step may be a step of preparing the second shell by injecting and reacting the prepared core/first shell in a second reactor containing a Group III precursor including at least one Group III element and a Group VI precursor including at least one Group VI element, wherein the second shell may have a molar ratio of the Group III element and the Group III element+the Group VI element of 1:10 to 1:2.

A core preparation step may comprise a step 1-1 and a step 1-2.

A step 1-1 may be a step of preparing a core solution by injecting and heating a silver precursor, an indium precursor, a gallium precursor, a sulfur precursor and a solvent in a first reactor.

A step 1-2 may be a step of adding a purification solvent to a core solution and centrifuging a resulting product, and dispersing a precipitate separated through centrifugation in a dispersion solvent.

A first shell preparation step may comprise a step 2-1 and a step 2-2.

A step 2-1 may be a step of injecting at least one of a Group I precursor and a Group III precursor including a Group III element in a second reactor containing an oleylamine.

A step 2-2 may be a step of injecting and reacting a purified core solution and a Group VI precursor including a Group VI element in a first reactor.

A second shell preparation step may comprise a step 3-1 and a step 3-2.

A step 2-1 may be a step of injecting a Group III precursor including a Group III element in a second reactor containing an oleylamine.

A step 2-2 may be a step of injecting and reacting a purified core/first shell solution and a Group VI precursor including a Group VI element in a first reactor.

In another aspect, embodiments of the present disclosure may provide an electronic device comprising a display device including a light emitting diode including a quantum dot, and a controller driving the display device. The quantum dot may comprise a core, a first shell, and a second shell. The core may include silver (Ag), indium (In), gallium (Ga) and sulfur(S). The first shell may be disposed on the core, and include at least one Group I element, at least one Group III element and at least one Group VI element. The first shell may have a molar ratio of the Group III element and the Group I element+the Group III element+the Group VI element of 1:10 to 1:2. The second shell may be disposed on the first shell and include at least one Group III element and at least one Group VI element. The second shell may have a molar ratio of the Group III element and the Group III element+the Group VI element of 1:10 to 1:2.

### Advantageous Effects

In a quantum dot, method for manufacturing a quantum dot, and electronic device according to embodiments of the present disclosure, since the amounts of the component elements configured to form shells is specified, the wavelength and Full Width at Half Maximum of the quantum dot may be reduced.

In a quantum dot, method for manufacturing a quantum dot, and electronic device according to embodiments of the present disclosure, the luminescence efficiency of the quantum dot may be superior.

### DESCRIPTION OF DRAWINGS

FIG. 1 is a cross-sectional view illustrating a quantum dot according to an embodiment of the present disclosure;

FIG. 2 is a cross-sectional view illustrating the quantum dot according to another embodiment of the present disclosure;

FIG. 3 is a flowchart of a method of manufacturing the quantum dot according to another embodiment of the present disclosure;

FIG. 4 is a cross-sectional view illustrating an electronic device according to another embodiment of the present disclosure; and

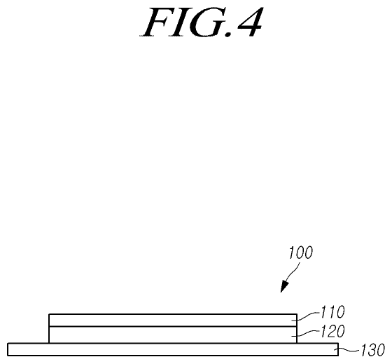

FIG. 5 is a cross-sectional view illustrating a light emitting diode according to another embodiment of the present disclosure.

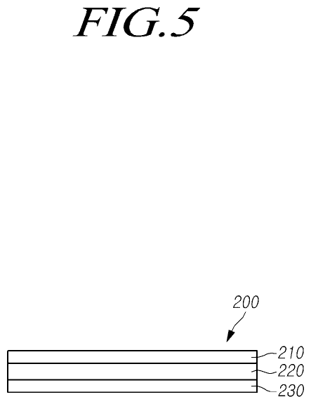

### MODE FOR INVENTION

Hereinafter, some embodiments of the present disclosure will be described in detail with reference to the accompanying illustrative drawings. In designating elements of the drawings by reference numerals, the same elements will be designated by the same reference numerals although they are shown in different drawings. Further, in the following description of the present disclosure, a detailed description of known functions and configurations incorporated herein will be omitted in the case in which the subject matter of the present disclosure may be rendered unclear thereby.

It will be understood that the terms “comprise”, “have”, “consist of”, and any variations thereof used herein are intended to cover non-exclusive inclusions unless explicitly stated to the contrary. Descriptions of elements in the singular form used herein are intended to include descriptions of elements in the plural form, unless explicitly stated to the contrary.

In addition, terms, such as first, second, A, B, (a), or (b), may be used herein when describing elements of the present disclosure. Each of these terminologies is not used to define an essence, order, or sequence of a corresponding element but used merely to distinguish the corresponding element from other elements.

It will be understood that when an element is referred to as being “connected”, “coupled”, or “joined” to another element, not only can it be “directly connected, coupled, or joined” to the other element, but it can also be “indirectly connected, coupled, or joined” to the other element via an “intervening” element. Here, the intervening element may be included in one or more of the two elements “connected”, “coupled”, or “joined” to each other.

In addition, it will be understood that when an element is referred to as being “above” or “on” another element, not only can it be “directly” above or on the other element, but it can also be “indirectly” above or on the other element or layer via an “intervening” element. In contrast, when an element is referred to as being “directly” above or on another element, it will be understood that no intervening element is interposed. In addition, when an element is referred to as being “above” or “on” a reference portion, the element is positioned above or below the reference portion but is not necessarily positioned “above” or “on” the reference portion in the opposite direction of gravity.

When time relative terms, such as “after”, “subsequent to”, “next”, “before”, and the like, are used to describe elements, operating or manufacturing methods, and the like, these terms may be used to describe non-consecutive or non-sequential processes or operations unless the term “directly” or “immediately” is used together.

In addition, when any numerical values for elements or corresponding information are mentioned, it should be considered that numerical values for elements or corresponding information include a tolerance or error range that may be caused by various factors (e.g., process factors, internal or external impact, noise, etc.) even when a relevant description is not specified.

The “diameter” of a nanostructure refers to the diameter of a cross-section normal to a first axis of the nanostructure, where the first axis has the greatest difference in length with respect to the second and third axes (the second and third axes are the two axes whose lengths most nearly equal each other). The first axis is not necessarily the longest axis of the nanostructure; e.g., for a disk-shaped nanostructure, the cross-section would be a substantially circular cross-section normal to the short longitudinal axis of the disk. Where the cross-section is not circular, the diameter is the average of the major and minor axes of that cross-section. For an elongated or high aspect ratio nanostructure, such as a nanowire, the diameter is measured across a cross-section perpendicular to the longest axis of the nanowire. For a spherical nanostructure, the diameter is measured from one side to the other through the center of the sphere.

The term “quantum dot” (or “dot”) refers to a nanocrystal that exhibits quantum confinement or exciton confinement. Quantum dots can be substantially homogenous in material properties, or in certain embodiments, can be heterogeneous, e.g., including a core and at least one shell. The optical properties of quantum dots can be influenced by their particle size, chemical composition, and/or surface composition, and can be determined by suitable optical testing available in the art. The ability to tailor the nanocrystal size, e.g., in the range between about 1 nm and about 15 nm, enables photoemission coverage in the entire optical spectrum to offer great versatility in color rendering.

As used herein, the term “shell” refers to material deposited onto the core or onto previously deposited shells of the same or different composition and that result from a single act of deposition of the shell material. The exact shell thickness depends on the material as well as the precursor input and conversion and can be reported in nanometers or monolayers. As used herein, “target shell thickness” refers to the intended shell thickness used for calculation of the required precursor amount. As used herein, “actual shell thickness” refers to the actually deposited amount of shell material after the synthesis and can be measured by methods known in the art. By way of example, actual shell thickness can be measured by comparing particle diameters determined from transmission electron microscopy (TEM) images of nanocrystals before and after a shell synthesis.

The term “Group”, as used herein, refers to a group of Periodic Table. The term “Period”, as used herein, refers to a period of Periodic Table.

As used herein, “Group I” may refer to Group IA (or 1A) and Group IB (or 1B), and examples of Group I elements may include Li, Na, K, Rb, Cs, Cu, Ag and Au, but are not limited thereto.

“Group II” may refer to Group IIA (or 2A) and Group IIB (or 2B), and examples of Group II elements may include Be, Mg, Ca, Sr, Zn, Cd and Hg, but are not limited thereto.

“Group III” may refer to Group IIIA (or 3A) and Group IIIB (or 3B), and examples of Group III elements may include In, Ga, Al and Tl, but are not limited thereto.

“Group V” may refer to Group VA (or 5A), and examples of Group V elements may include P, As, Sb, Bi and N, but are not limited thereto.

“Group VI” may refer to Group VIA (or 6A), and examples of Group VI elements may include S, Se and Te, but are not limited thereto.

The term “precursor”, as used herein, means a chemical compound previously manufactured to cause a quantum dot to react. The precursor is a concept referring to all chemicals including metals, ions, elements, compounds, complexes, composites, clusters, and the like. The precursor is not necessarily limited to the last material of any reaction, but means a material that may be produced in any predetermined step.

Hereinafter, quantum dot according to embodiments of the present disclosure is described below with reference to the accompanying drawings.

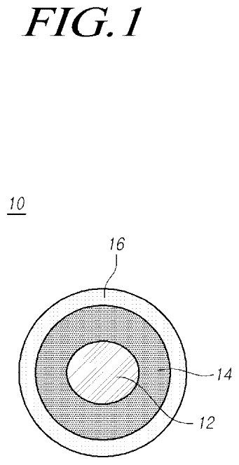

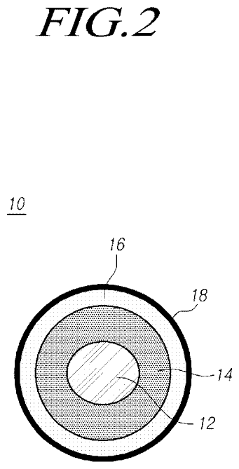

FIG. 1 is a cross-sectional view illustrating a quantum dot according to an embodiment of the present disclosure. FIG. 2 is a cross-sectional view illustrating the quantum dot according to another embodiment of the present disclosure.

Referring to FIG. 1, a quantum dot 10 according to the embodiments of the present disclosure may include a core 12 and a first shell 14, a second shell 16. T quantum dot 10 may further include another shell 18 outside the second shell 16 as illustrated in FIG. 2, or may further include another intermediate shell (not shown) between the first shell 14 and the second shell 16.

The core 12 may include Ag, In, Ga and S. That is, the core 10 may be a tetra-element compound comprising Ag such as a Group I element, In and Ga such as a Group III element, and S such as a Group VI element. The core 12 may be doped with metals or non-metals. The core 12 may be purified before deposition of the first shell 14 and the second shell 16. The core 12 may be filtered to remove precipitate from a core solution.

The first shell 14 may include at least one of a Group I element and a Group III element, and a Group VI element.

As described above, “Group I” may refer to Group IA (or 1A) and Group IB (or 1B), and examples of Group I elements may include Li, Na, K, Rb, Cs, Cu, Ag and Au, but are not limited thereto.

The Group I element included in the first shell 14 may or may not be identical to Ag included in the core 12. Since the first shell 14 simultaneously includes the Group I element included in the core 12, vacancy defects on the surface of the core 12 may be removed or supplemented.

The first shell 14 may include one Group I element or may include two or more different Group I elements. For example, in the case of the first shell 14 including two or more different Group I elements, the first shell 14 may include the Group IA (or 1A) element and the Group IB (or 1B) element. As an example, the Group IA (or 1A) element may be Na, and the Group IB (or 1B) element may be Cu or Ag.

Since the first shell 14 includes the Group I element included in the core 12, vacancy defects on the surface of the core 12 may be removed or supplemented.

As described above, “Group III” may refer to Group IIIA (or 3A) and Group IIIB (or 3B), and examples of Group III elements may include In, Ga, Al and Tl, but are not limited thereto. “Group VI” may refer to Group VIA (or 6A), and examples of Group VI elements may include S, Se and Te, but are not limited thereto.

The first shell may have a molar ratio of the Group III element and the Group I element+the Group III element+the Group VI element of 1:10 to 1:2.

In case that the molar ratio of the Group III element and the Group I element+the Group III element+the Group VI element is less than 1:10 and then the precursors configured to from component material in cationic complex systems such as I-III-IV has more anions than cations, the first shell 14 may have a bond with the core other than the I-III-VI composition to be obtained. Since only the core 12 exists without the first shell 14 on the core 12, the wavelength and Full Width at Half Maximum are increased as a result.

Conversely, in case that the molar ratio of the Group III element and the Group I element+the Group III element+the Group VI element is greater than 1:2, and then cations are much more than anions, the first shell undergoes cation exchange with the core, and the relative thickness of the shell increases and uneven growth of the core occurs. Therefore, the improvement of the optical characteristics is limited.

However, the first shell 14 may obtain a more excellent and homogeneous structure of the first shell 14 when the molar ratio of the Group III element and the Group I element+the Group III element+the Group VI element is 1:10 to 1:2, that is, when the amounts of precursors configured to form the first shell 14 are uniform, or when the cations are less than the anions. The result of the improvement in the optical characteristics as the group III element increases is the result of the well-formed III-VI first shell 14, and may be expressed as a result of an increase in the luminescence efficiency and a decrease in Full Width at Half Maximum.

The first shell 14 may have the molar ratio of the Group III element and the Group I element+the Group III element+the Group VI element of 3:10 to 1:2. According to the molar ratio as described above, a more excellent and homogeneous structure of the first shell 14 may be obtained. The result of the improvement in the optical characteristics as the group III element increases further is the result of the well-formed III-VI first shell 14, and may be expressed as a result of an increase in the luminescence efficiency and a decrease in Full Width at Half Maximum.

For example, the luminescence efficiency of only the core 12 and the first shell 14 may have 68.2% to 77.2% (See Table 1 below).

The first shell 14 may be doped with metals or non-metals. The core 12/first shell 14 may be purified after deposition of the first shell 14. The core 12/first shell 14 may be filtered to remove precipitate from a core solution.

The first shell 14 may additionally include another doped Group I element.

The second shell 16 may surround the first shell 14 while being positioned on the first shell 14 and may include at least one of Group III elements and at least one of Group VI elements. The Group III element included in the second shell 16 may or may not be identical to In and Ga included in the core 12. The Group VI element included in the second shell 16 may or may not be identical to S included in the core 12.

The second shell may have a molar ratio of the Group III element and the Group III element+the Group VI element of 1:10 to 1:2.

In the configuration of the second shell 16 which is not a complex system, since the molar ratio of the group III elements and the group III elements+group VI elements in the second shell 16 is 1:10 to 1:2, when the amounts of precursors configured to form the second shell 16 are uniform or the cations are less than the anions, it is more effective in forming a homogeneous III-VI second shell 16, so that the optical characteristics may be improved by suppressing interface defects between the first shell 14 and the second shell 16 rather than the formation of other compositions.

In addition, by controlling the stoichiometry in the reaction adjacent to the core 12 or the first shell 14, the first shell 14 or the second shell 16, the second shell 16 may be effectively formed, thereby showing a decrease in Full Width at Half Maximum and an increase in the luminescence efficiency.

The second shell 16 may have the molar ratio of the Group III element and the Group III element+the Group VI element of 3:10 to 1:2. According to the molar ratio as described above, a more excellent and homogeneous structure of the second shell 16 may be obtained.

The luminescence efficiency of the core 12, the first shell 14 and the second shell 16 may have 85.3% to 95.4% (See Table 1 below).

The second shell 16 may be doped with metals or non-metals. The core 12/first shell 14/second shell 16 may be purified after deposition of the second shell 16. The core 12/first shell 14/second shell 16 may be filtered to remove precipitate from a core solution.

The second shell 16 may additionally include another doped Group III element.

The thickness of the first shell 14 may be 2.9 nm to 4.2 nm and the thickness of the second shell 16 may be 0.8 nm to 2.5 nm. In addition, the thickness of the first shell 14 may be 2.9 nm to 3.9 nm and the thickness of the second shell 16 may be 0.8 nm to 1.6 nm.

The first shell 14 may be entirely crystalline, and the second shell 16 may be entirely amorphous. As used herein, the term “entirely” crystalline or amorphous means that more than 70% of the shell may be crystalline or amorphous, more than 85% of the shell may be crystalline or amorphous, or more than 95% of the shell may be crystalline or amorphous.

The first shell 14 may include one of AgAlS, AgAlSe, AgAlTe, AgGaS, AgGaSe, AgGaTe, AgInS, AgInSe, AgInTe, AgTiS, AgTiSe, AgTiTe, CuAlS, CuAlSe, CuAlTe, CuGaS, CuGaSe, CuGaTe, CuInS, CulnSe, CuInTe, CuTiS, CuTiSe, CuTiTe, AuAlS, AuAlSe, AuAlTe, AuGaS, AuGaSe, AuGaTe, AuInS, AuInSe, AulnTe, AuTiS, AuTiSe, and AuTiTe.

In addition, the second shell 16 may include one of AlS, AlSe, AlTe, GaS, GaSe, GaTe, InS, InSe, InTe, TiS, TiSe, and TiTe.

The shape or form of the quantum dot 10 is not particularly limited and may be any form available in the art. More specifically, the quantum dot 10 may be shaped as a spherical, pyramidal, multi-arm, or cubic nanoparticle, nanotube, nanowire, nanofiber, or nanoplatelet particle.

The quantum dot 10 may adjust the color of the emitted light according to the particle size, and accordingly, the quantum dot 10 may have various emission colors such as blue, red, and green.

According to an embodiment, the diameter of the quantum dot 10 may be 3 nm to 20 nm.

In another aspect, embodiments of the present disclosure may provide a method of manufacturing a quantum dot.

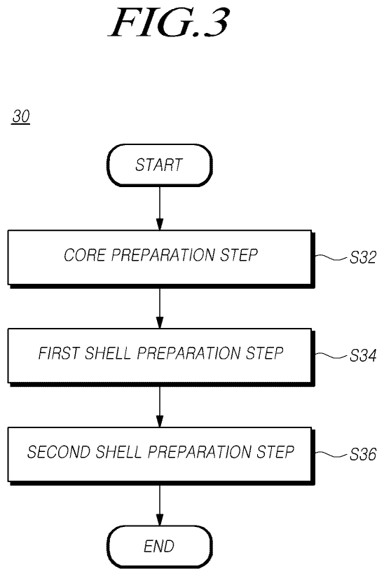

FIG. 3 is a flowchart of a method of manufacturing a quantum dot according to another embodiment of the present disclosure.

Referring to FIG. 3, the method 20 of manufacturing the quantum dot according to embodiments of the present disclosure may comprise a core preparation step S22, a first shell preparation step S24, and a second shell preparation step S26.

In the method 20 of manufacturing the quantum dot according to embodiments of the present disclosure, features of the core, the first shell and the second shell are the same as those of the core 12, the first shell 14, and the second shell 16 described for the quantum dot 10 according to above embodiments, unless clearly stated otherwise.

The method 20 of manufacturing the quantum dot may be performed by preparing a core using a silver precursor, an indium precursor, a gallium precursor, and a sulfur precursor in a heated reactor, and then by preparing the prepared core together with precursors for preparing a first shell and a second shell using a hot-injection method and a heating up method. In addition, the hot-injection method and the heating up method may be performed in each step of the core preparation step S22 and the first and second shell preparation step S24 and S26.

The core preparation step S22 may be a step of preparing the core.

The first shell preparation step S24 may be a step of preparing a first shell by injecting and reacting a prepared core in a first reactor containing at least one of a Group I precursor including a Group I element and a Group III precursor including a Group III element, and a Group VI precursor including a Group VI element. Wherein the first shell may have a molar ratio of the Group III element and the Group I element+the Group III element+the Group VI element of 1:10 to 1:2.

The second shell preparation step may be a step of preparing a second shell by injecting and reacting a prepared core/first shell in a second reactor containing a Group III precursor including at least one Group III element and a Group VI precursor including at least one Group VI element. Wherein the second shell may have a molar ratio of the Group III element and the Group III element+the Group VI element of 1:10 to 1:2.

The core preparation step S22 may be the step of preparing the core. The core preparation step may comprise a step 1-1 and a step 1-2.

The step 1-1 may be a step of preparing the core solution by injecting and heating the silver precursor, the indium precursor, the gallium precursor, the sulfur precursor and the solvent in the first reactor.

The silver precursor injected in the step 1-1 may include, for example, one or more selected from silver (I) acetylacetonate, silver (I) chloride, silver (I) bromide, silver (I) iodide, silver (I) acetate, silver (I) nitrate, and silver (I) myristate.

The indium precursor injected in the step 1-1 may include, for example, one or more selected from indium (III) acetylacetonate, indium (III) chloride, indium (III) acetate, trimethyl indium, alkyl indium, aryl indium, indium (III) myristate, and indium (III) myristate acetate.

The gallium precursor injected in the step 1-1 may include, for example, one or more selected from gallium (III) acetylacetonate, gallium (III) chloride, gallium (III) iodide, gallium (III) bromide, gallium (III) acetate, and gallium (III) nitrate.

The sulfur precursor injected in the step 1-1 may include, for example, one or more selected from alkyl thiols, such as n-butanethiol, isobutane thiol, n-haxanethiol, 1-octanethiol, decanethiol, 1-dodecanethiol, hexadecanethiol, and octadecanethiol, sulfur chloride, sulfur(S), S-TOP, S-ODE, S-toluene, S-oleylamine, and N,N-dimethylthiourea.

The solvent injected in the step 1-1 may include, for example, one or more selected from oleylamine, 1-octadecene, and trioctylamine, but are not limited thereto.

The silver precursor, the indium precursor, the gallium precursor, and the sulfur precursor injected in the step 1-1 may each be precursor solution mixed with the solvent.

The core solution including the core may be prepared by the step 1-1, and the core may be formed by reacting the silver precursor, the indium precursor, the gallium precursor, and the sulfur precursor in the first reactor.

The step 1-2 may be a step of adding a purification solvent to the core solution and centrifuging a resulting product, and dispersing a precipitate separated through centrifugation in a dispersion solvent.

For example, the step 1-2 may be a step of adding the purification solvent, such as methanol, ethanol, acetone, and 2-propanol (IPA), to the core solution and centrifuging the resulting product, and dispersing the precipitate separated through centrifugation in the dispersion solvent, such as hexane, toluene, octadecane, heptane, oleylamine, and 1-octadecene.

The purified core solution may be prepared by the step 1-2.

In the step 1-1, the core solution may be prepared by injecting and heating the silver precursor, the indium precursor, the gallium precursor, the sulfur precursor, and the solvent in the first reactor.

The step 2-1 may be a step of injecting at least one of the Group I precursor and the Group III precursors including Group III element in the second reactor containing an oleylamine.

The step 2-2 may be a step of injecting and reacting the purified core solution and the Group VI precursor in the first reactor.

The Group I element in the first shell may include one or more selected from Li, Na, Cu, Ag, and Au, but are not limited thereto. The first shell may include one Group I element or may include two or more different Group I elements. The first shell may include at least one Group I element and elements of other Groups as described below. The first shell 14 may be doped with metals or non-metals. At least one Group I element in the first shell may include one or more selected from Cu, Ag, and Au.

The Group III element in the first shell may include one or more selected from In, Ga, Al, and Tl, but are not limited thereto. The Group VI element may include one or more selected from S, Se, and Te, but are not limited thereto.

The first shell preparation step S24 may be the step of preparing the first shell by injecting and reacting the prepared core in the first reactor containing the Group I precursor including at least one Group I element.

In an aspect, when the first shell additionally includes at least one Group III element and at least one Group VI element, the first shell preparation step S24 may be the step of preparing the first shell by injecting and reacting the prepared core and the Group VI precursor in the first reactor containing the Group I precursor including at least one Group I element and the Group III precursor additionally including at least one Group III element.

The first shell preparation step S24 may comprise a step 2-1 and a step 2-2.

The step 2-1 may be a step of injecting at least one of the Group I precursor and the Group III precursor including Group III element in the second reactor containing an oleylamine.

The step 2-2 may be a step of reacting the purified core solution and the Group VI precursor in the first reactor.

The first precursor injected in a step 2-1 may include, e.g., one or more selected from the group consisting of chloride, iodide, oxide and acetylacetonate chemically bonded with at least one Group I element.

For example, when the Group I element is Ag, the first precursor may be silver (I) chloride, silver (I) iodide, silver (I) oxidee, or silver (I) acetylacetonate.

The Group III precursor and the Group VI precursor injected in the step 2-1 and the step 2-2 may include, e.g., one or more selected from the group consisting of acetate, acetylacetonate, oxide, bromide, chloride and iodide chemically bonded with at least one Group III element.

For example, when the Group III precursor injected in the step 2-1 is a gallium precursor, the gallium precursor may be one or more selected from the group consisting of gallium (III) acetate, gallium (III) acetylacetonate, gallium (III) oxide, gallium (III) bromide, gallium (III) chloride, and gallium (III) iodide.

When the Group III precursor injected in the step 2-1 is an indium precursor, the indium precursor has already been described in connection with the step 1-1, and thus a description thereof will be omitted.

When the Group VI precursor injected in the step 2-2 is a sulfur precursor, the sulfur precursor has already been described in connection with the step 1-1, and thus a description thereof will be omitted.

When the Group VI precursor injected in the step 2-2 is a selenium precursor, the selenium precursor may be, e.g., one or more selected from the group consisting of selenium chloride, selenium (Se), Se-TOP, Se-DPP, Se-ODE, and organic selenium compounds, e.g., compounds such as dibenzyl diselenide, diphenyl diselenide, or selenium hydride.

When the Group VI precursor injected in the step 2-2 is a tellurium precursor, the tellurium precursor may be, e.g., one or more selected from the group consisting of tellurium chloride, tellurium (Te), and tellurium hydride.

The second shell preparation step S26 may comprise a step 3-1 and a step 3-2.

The step 2-1 may be a step of injecting the Group III precursor including Group III element in the second reactor containing an oleylamine.

The step 2-2 may be a step of injecting and reacting the purified core/first shell solution and the Group VI precursor including the Group VI element in the first reactor.

The Group III element included in the second shell may include one or more selected from In, Ga, Al, and Tl, but are not limited thereto. The Group VI element included in the second shell may include one or more selected from S, Se, and Te, but are not limited thereto. The Group VI element included in the second shell may or may not be identical to S included in the core.

The first shell prepared in the first shell preparation step S24 may have the molar ratio of the Group III element and the Group I element+the Group III element+the Group VI element of 1:10 to 1:2. The first shell 14 may have the molar ratio of the Group III element and the Group I element+the Group III element+the Group VI element of 3:10 to 1:2. According to the molar ratio as described above, a more excellent and homogeneous structure of the first shell 14 may be obtained. The result of the improvement in the optical characteristics as the group III element increases further is the result of the well-formed III-VI first shell 14, and may be expressed as a result of an increase in the luminescence efficiency and a decrease in Full Width at Half Maximum.

The second shell prepared in the second shell preparation step S26 may have the molar ratio of the Group III element and the Group III element+the Group VI element of 1:10 to 1:2. The second shell 16 may have the molar ratio of the Group III element and the Group III element+the Group VI element of 3:10 to 1:2. According to the molar ratio as described above, a more excellent and homogeneous structure of the second shell 16 may be obtained.

The thickness of the first shell prepared in the first shell preparation step S24 may be 2.9 nm to 4.2 nm and the thickness of the second shell prepared in the second shell preparation step S26 may be 0.8 nm to 2.5 nm. In addition, the thickness of the first shell prepared in the first shell preparation step S24 may be 2.9 nm to 3.9 nm and the thickness of the second shell prepared in the second shell preparation step S26 may be 0.8 nm to 1.6 nm.

The first shell prepared in the first shell preparation step S24 may be entirely crystalline, and the second shell prepared in the second shell preparation step S26 may be entirely amorphous.

The first shell prepared in the first shell preparation step S24 may include one of AgAlS, AgAlSe, AgAlTe, AgGaS, AgGaSe, AgGaTe, AgInS, AgInSe, AgInTe, AgTiS, AgTiSe, AgTiTe, CuAlS, CuAlSe, CuAlTe, CuGaS, CuGaSe, CuGaTe, CuInS, CuInSe, CuInTe, CuTiS, CuTiSe, CuTiTe, AuAlS, AuAlSe, AuAlTe, AuGaS, AuGaSe, AuGaTe, AuInS, AuInSe, AuInTe, AuTiS, AuTiSe, and AuTiTe.

In addition, the second shell prepared in the second shell preparation step S26 may include one of AlS, AlSe, AlTe, GaS, GaSe, GaTe, InS, InSe, InTe, TiS, TiSe, and TiTe.

In another aspect, according to embodiments of the present disclosure, there may be provided an ink composition comprising the quantum dot 10 described with reference to FIG. 1 or the quantum dot prepared in the method 20 described with reference to FIG. 3. In the ink composition according to embodiments of the present disclosure, the quantum dot is the same as the quantum dot 10 according to embodiments of the disclosure unless otherwise described.

The ink composition according to the present embodiments may be a light conversion ink composition including quantum dots 10, a light curable monomer, a light initiator, and a light diffuser.

According to an embodiment, the content of the quantum dot 10 may be 20 parts by weight to 60 parts by weight, e.g., 25 parts by weight to 50 parts by weight, or 30 parts by weight to 45 parts by weight, with respect to the total content of 100 parts by weight of the quantum dot ink composition. According to an embodiment, the ink composition may not include a solvent. In other words, the ink composition may be a solvent-free quantum dot ink composition. According to an embodiment, the ink composition may have a viscosity of 10 cP to 25 cP. According to an embodiment, the surface tension of the ink composition at 25° C. may be 30 mN/m or more. When the above viscosity and/or surface tension range is satisfied, the ink composition, as a solvent-free quantum dot ink composition, may appropriately use various members, such as a color conversion member or an emission layer of an emission device, in a solution process such as an inkjet.

According to an embodiment, an optical member formed using an ink composition may be provided. For example, the optical member may be a color conversion member.

According to another aspect, referring to FIG. 6, an electronic device 100 according to an embodiment may include a substrate 110, a light source 120 disposed on the substrate 110, and a color conversion member 130 disposed in a path of light emitted from the light source 120, and the color conversion member 130 may be formed using the above ink composition.

According to an embodiment, the light source 120 may be an emission device. For example, the light source 120 may be an organic light emitting diode (OLED) or an inorganic light emitting diode (ILED or QLED).

In another aspect, referring to FIG. 7, the light emitting diode 200 according to another embodiment may include quantum dot 10. The light emitting diode 200 according to other embodiments may include a positive electrode 210, a negative electrode 230, and an intermediate layer 220 positioned therebetween. The intermediate layer 220 may include an emission layer including an ink composition including the above quantum dot.

According to another aspect of the disclosure, there may be provided an electronic device including a display device including the above light emitting diode and a controller for driving the display device.

The electronic device may include, e.g., a display device, a lighting device, a solar cell, a portable or mobile terminal (e.g., a smartphone, a tablet, a PDA, an electronic dictionary, a PMP, etc.), a navigation terminal, a game console, various TVs, various computer monitors, etc., but without limitations thereto, may include any type of device that includes the component(s).

Applications to various electronic devices and devices using quantum dot 10 may be easily applied by those skilled in the art, and thus detailed descriptions thereof will be omitted.

Hereinafter, specific embodiments are presented. However, the embodiments described below are merely for specifically illustrating or describing the disclosure, and the scope of the disclosure is not limited thereto.

The description may refer to an example in which the Group I element used in the first shell is Ag, the Group III element used in the first shell is Ga, and the Group VI element used in the first shell is S., used in the first shell. Since the method for manufacturing the core and the first and second shells in the same manner as in the examples below using the elements described in the above-described examples may be typical technologies, the detailed descriptions thereon are omitted.

### Embodiment

### (1) Preparing Precursors

### (Preparation Example 1) Preparing Silver (I) Iodide-Oleylamine Precursor Solution

0.56 g (2.4 mmol) of silver (I) iodide and 10 mL (30 mmol) of oleylamine were placed in a 50 mL flask, decompressed at room temperature (RT) for 1 hour, heated to 120° C. for 10 minutes, and then reacted for 1 hour. The mixed solution was cooled to room temperature in an Ar atmosphere to prepare an Ag precursor solution. The Ag concentration of the precursor solution was 0.24 M.

### (Preparation Example 2) Preparing Indium (III) Chloride-Ethanol Precursor Solution

0.11 g (0.5 mmol) of indium (III) chloride and 5 mL of ethanol were placed in 10 mL vial to prepare an In precursor solution. The In concentration of the precursor solution was 0.10 M.

### (Preparation Example 3): Preparing Gallium (III) Chloride-Toluene Precursor Solution

0.80 g (4.54 mmol) of gallium (III) chloride and 0.8 mL of toluene were placed in 10 mL vial to prepare a Ga precursor solution. The Ga concentration of the precursor solution was 5.68 M.

### (Preparation Example 4) Preparing Gallium (III) Acetylacetonate-Toluene Precursor Solution

1.67 g (4.54 mmol) of gallium (III) chloride and 16 mL of toluene were placed in 20 mL vial to prepare a Ga precursor solution. The Ga concentration of the precursor solution was 0.28 M.

### (Preparation Example 5) Preparing S-Oleylamine Precursor Solution

0.305 g (9.5 mmol) of S and 9.5 mL (28.5 mmol) of oleylamine were placed in a 50 mL flask, decompressed at room temperature (RT) for 30 minutes, heated to 120° C. for 10 minutes, and then reacted for 1 hour. The mixed solution was cooled to room temperature in an Ar atmosphere to prepare an S precursor solution. The S concentration of the precursor solution was 1 M.

### (2) Preparing AgInGaS Quantum Dot Core

1) 0.3 g of gallium (III) acetylacetonate and trioctylphosphine oxide (TOPO) prepared in Preparation Example 4, 5 ml of silver (I) iodide-oleylamine prepared in Preparation Example 1, indium (III) chloride-ethanol prepared in Preparation Example 2 and 1-octadecene were placed in a round flask of 50 mL having a refluxer and heated to 120° C. while being maintained at about 0.005 torr using a vacuum pump for 30 minutes.

2) Then, after substituting with an N₂ atmosphere, 1 ml (0.03 g, 1 mmol) of the S-oleylamine solution prepared in Preparation Example 5 and 0.5 ml of 1-dodecanethiol were injected at 120° C.

3) After the S-oleylamine solution was added, it was maintained at 0.005 torr using a vacuum pump at 120° C. for 30 minutes. Then, the reaction was terminated after stirring at 190° C. for 10 minutes.

4) 5 ml of tris(dimethylamino)phosphine ((PDEA) 3)+trioctylphosphine (TOP) mixed solution was injected at 280° C. and was then cooled to room temperature.

5) The prepared AgInGaS quantum dot solution was divided into two and was filled with 42.5 ml of ethanol, preparing 50 ml of AgInGaS core-ethanol solution.

6) The solution was centrifuged at 5000 RPM for 5 minutes and then dispersed in 1.2 ml of toluene. The dispersed AgInGaS core-toluene solution was centrifuged at 5000 RPM for 1 minute to remove impurities, obtaining an AgInGaS core quantum dot solution.

### (3) Example 1: Preparing AgInGaS/AgGaS Quantum Dots (Ga/(Ag+Ga+S))=0.1

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot core of (2) was injected, 0.5 mmol of silver (I) iodide, 0.8 mmol of gallium (III) chloride and 5 mol of sulfur were injected, and toluene was removed using a vacuum pump. Then, after substitution with a nitrogen atmosphere, the reaction proceeded at 310° C. for 60 minutes. 2) 5 ml of tris(dimethylamino)phosphine ((PDEA)₃)+trioctylphosphine (TOP) mixed solution was injected at 280° C. and cooled to room temperature, obtaining an AgInGaS/AgGaS quantum dot solution.

3) As a result of ICP measurement, it was confirmed that the ratio of Ga included in the core of the above prepared quantum dot and Ag, Ga and S included in the first shell was 0.1.

### (4) Example 2: Preparing AgInGaS/AgGaS Quantum Dots (Ga/(Ag+Ga+S))=0.2

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot core of (2) was injected, 0.2 mmol of silver (I) iodide, 1 mmol of gallium (III) chloride and 5 mol of sulfur were injected, and toluene was removed using a vacuum pump. Then, after substitution with a nitrogen atmosphere, the reaction proceeded at 310° C. for 60 minutes.

2) 5 ml of tris(dimethylamino)phosphine ((PDEA) 3)+trioctylphosphine (TOP) mixed solution was injected at 280° C. and cooled to room temperature, obtaining an AgInGaS/AgGaS quantum dot solution.

3) As a result of ICP measurement, it was confirmed that the ratio of Ga included in the core of the above prepared quantum dot and Ag, Ga and S included in the first shell was 0.2.

### (5) Example 3: Preparing AgInGaS/AgGaS Quantum Dots (Ga/(Ag+Ga+S))=0.3

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot core of (2) was injected, mmol of silver (I) iodide, 3 mmol of gallium (III) chloride and 4.2 mol of sulfur were injected, and toluene was removed using a vacuum pump. Then, after substitution with a nitrogen atmosphere, the reaction proceeded at 310° C. for 60 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS quantum dot solution.

3) As a result of ICP measurement, it was confirmed that the ratio of Ga included in the core of the above prepared quantum dot and Ag, Ga and S included in the first shell was 0.3.

### (6) Example 4: Preparing AgInGaS/AgGaS Quantum Dots (Ga/(Ag+Ga+S))=0.4

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot core of (2) was injected, 0.13 mmol of silver (I) iodide, 5 mmol of gallium (III) chloride and 6 mol of sulfur were injected, and toluene was removed using a vacuum pump. Then, after substitution with a nitrogen atmosphere, the reaction proceeded at 310° C. for 60 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS quantum dot solution.

3) As a result of ICP measurement, it was confirmed that the ratio of Ga included in the core of the above prepared quantum dot and Ag, Ga and S included in the first shell was 0.4.

### (7) Example 5: Preparing AgInGaS/AgGaS Quantum Dots (Ga/(Ag+Ga+S))=0.5

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot core of (2) was injected, 0.13 mmol of silver (I) iodide, 7 mmol of gallium (III) chloride and 6 mol of sulfur were injected, and toluene was removed using a vacuum pump. Then, after substitution with a nitrogen atmosphere, the reaction proceeded at 310° C. for 60 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS quantum dot solution.

3) As a result of ICP measurement, it was confirmed that the ratio of Ga included in the core of the above prepared quantum dot and Ag, Ga and S included in the first shell was 0.5.

### (8) Example 6: Preparing AgInGaS/AgGaS/GaS Quantum Dots (Ga/(Ga+S))=0.1

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot solution of Example 5 was injected, 0.8 mmol of gallium (III) chloride and 5 mol of sulfur were injected, and toluene was removed using a vacuum pump. Then, after substitution with a nitrogen atmosphere, the reaction proceeded at 310° C. for 100 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS/GaS quantum dot solution.

3) As a result of ICP measurement, it was confirmed that the ratio of Ga included in the first shell of the above prepared quantum dot and Ga and S included in the second shell was 0.1.

### (9) Example 7: Preparing AgInGaS/AgGaS/GaS Quantum Dots (Ga/(Ga+S))=0.2

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot solution of Example 5 was injected, 1 mmol of gallium (III) chloride and 4.5 mol of sulfur were injected, and toluene was removed using a vacuum pump. Then, after substitution with a nitrogen atmosphere, the reaction proceeded at 310° C. for 100 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS/GaS quantum dot solution.

3) As a result of ICP measurement, it was confirmed that the ratio of Ga included in the first shell of the above prepared quantum dot and Ga and S included in the second shell was 0.2.

### (10) Example 8: Preparing AgInGaS/AgGaS/GaS Quantum Dots (Ga/(Ga+S))=0.3

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot solution of Example 5 was injected, 2.4 mmol of gallium (III) chloride and 5.2 mol of sulfur were injected, and toluene was removed using a vacuum pump. Then, after substitution with a nitrogen atmosphere, the reaction proceeded at 310° C. for 100 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS/GaS quantum dot solution.

3) As a result of ICP measurement, it was confirmed that the ratio of Ga included in the first shell of the above prepared quantum dot and Ga and S included in the second shell was 0.3.

### (11) Example 9: Preparing AgInGaS/AgGaS/GaS Quantum Dots (Ga/(Ga+S))=0.4

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot solution of Example 5 was injected, 4.2 mmol of gallium (III) chloride and 5.2 mol of sulfur were injected, and toluene was removed using a vacuum pump. Then, after substitution with a nitrogen atmosphere, the reaction proceeded at 310° C. for 100 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS/GaS quantum dot solution.

3) As a result of ICP measurement, it was confirmed that the ratio of Ga included in the first shell of the above prepared quantum dot and Ga and S included in the second shell was 0.4.

### (12) Example 10: Preparing AgInGaS/AgGaS/GaS Quantum Dots (Ga/(Ga+S))=0.5

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot solution of Example 5 was injected, 6.2 mmol of gallium (III) chloride and 4.2 mol of sulfur were injected, and toluene was removed using a vacuum pump. Then, after substitution with a nitrogen atmosphere, the reaction proceeded at 310° C. for 100 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS/GaS quantum dot solution.

3) As a result of ICP measurement, it was confirmed that the ratio of Ga included in the first shell of the above prepared quantum dot and Ga and S included in the second shell was 0.5.

### (13) Comparative Example 1: First Shell (Ga/(Ag+Ga+S))=0.05 (AgInGaS/AgGaS)

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot core of (2) was injected, 0.1 mmol of silver (I) iodide, 3 mmol of gallium (III) chloride and 48 mol of sulfur were injected, and toluene was removed using a vacuum pump. Then, after substitution with a nitrogen atmosphere, the reaction proceeded at 310° C. for 60 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS quantum dot solution.

3) As a result of ICP measurement, it was confirmed that the ratio of Ga included in the core of the above prepared quantum dot and Ag, Ga and S included in the first shell was 0.05.

### (14) Comparative Example 2: Second Shell (Ga/(Ga+S))=0.05 (AgInGaS/AgGaS/GaS)

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot core of Comparative Example 1 was injected, 3 mmol of gallium (III) chloride and 48 mol of sulfur were injected, and toluene was removed using a vacuum pump. Then, after substitution with a nitrogen atmosphere, the reaction proceeded at 310° C. for 100 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS/GaS quantum dot solution.

3) As a result of ICP measurement, it was confirmed that the ratio of Ga included in the first shell of the above prepared quantum dot and Ga and S included in the second shell was 0.05.

### (15) Comparative Example 3: First Shell (Ga/(Ag+Ga+S))=0.05 (AgInGaS/AgGaS)

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot core of (2) was injected, 0.1 mmol of silver (I) iodide, 41 mmol of gallium (III) chloride and 3 mol of sulfur were injected, and toluene was removed using a vacuum pump. Then, after substitution with a nitrogen atmosphere, the reaction proceeded at 310° C. for 60 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS quantum dot solution.

3) As a result of ICP measurement, it was confirmed that the ratio of Ga included in the core of the above prepared quantum dot and Ag, Ga and S included in the first shell was 0.95.

### (16) Comparative Example 4: Second Shell (Ga/(Ga+S))=0.09 (AgInGaS/AgGaS/GaS)

1) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the quantum dot core of Comparative Example 3 was injected, 41 mmol of gallium (III) chloride and 3 mol of sulfur were injected, and toluene was removed using a vacuum pump. Then, after substitution with a nitrogen atmosphere, the reaction proceeded at 310° C. for 100 minutes.

2) 5 ml of tris(dimethylamino)phosphine ((PDEA)₃)+trioctylphosphine (TOP) mixed solution was injected at 280° C. and cooled to room temperature, obtaining an AgInGaS/AgGaS/GaS quantum dot solution.

3) As a result of ICP measurement, it was confirmed that the ratio of Ga included in the first shell of the above prepared quantum dot and Ga and S included in the second shell was 0.95.

### Experimental Example

For the quantum dots manufactured as above according to Examples 1 to 10 and Comparative Examples 1 to 4, the optical characteristics of the quantum dots [Emission Peak, Quantum Yield, Full Width at Half Maximum (FWHM)] were confirmed using the QE-2000 device of Otsuka Electronics.

Table 1 below illustrates the evaluation results of the optical characteristics of the prepared quantum dots.

TABLE 1

| | | | | Em. | | |
|---|---|---|---|---|---|---|
| | ICP data | | | peak | FWHM | QY |
| | Ag | Ga | S | (nm) | (nm) | (%) |
| Example 1 | 0.3 | 0.4 | 3 | 530 | 30.2 | 68.2 |
| (Ga/Ag + Ga + S) = 0.1 | | | | | | |
| Example 2 | 0.1 | 0.8 | 3 | 530.3 | 30 | 71 |
| (Ga/Ag + Ga + S) = 0.2 | | | | | | |
| Example 3 | 0.03 | 1 | 2.2 | 530.2 | 29.2 | 76 |
| (Ga/Ag + Ga + S) = 0.3 | | | | | | |
| Example 4 | 0.03 | 3 | 4.2 | 530.2 | 29.5 | 75.8 |
| (Ga/Ag + Ga + S) = 0.4 | | | | | | |
| Example 5 | 0.03 | 4.3 | 4.2 | 530.7 | 29.8 | 77.2 |
| (Ga/Ag + Ga + S) = 0.5 | | | | | | |
| Example 6 | | 0.4 | 3 | 531.2 | 29.2 | 85.3 |
| (Ga/Ga + S) = 0.1 | | | | | | |
| Example 7 | | 0.8 | 3 | 531.5 | 29.2 | 88.2 |
| (Ga/Ga + S) = 0.2 | | | | | | |
| Example 8 | | 1.4 | 3.2 | 532 | 29.2 | 93.1 |
| (Ga/Ga + S) = 0.3 | | | | | | |
| Example 9 | | 2.2 | 3.2 | 532.1 | 29.2 | 93.7 |
| (Ga/Ga + S) = 0.4 | | | | | | |
| Example 10 | | 3.2 | 3.2 | 532 | 29.2 | 95.4 |
| (Ga/Ga + S) = 0.5 | | | | | | |
| Com. Exm. 1 | 0.03 | 1 | 19 | 528.1 | 33 | 35 |
| (Ga/Ag + Ga + S) = 0.05 | | | | | | |
| Com. Exm. 2 | | 1 | 19 | 529.5 | 33 | 47 |
| (Ga/Ga + S) = 0.05 | | | | | | |
| Com. Exm. 3 | 0.03 | 19 | 1 | 524.3 | 42 | 21 |
| (Ga/Ag + Ga + S) = 0.95 | | | | | | |
| Com. Exm. 4 | | 19 | 1 | 524.5 | 41 | 34 |
| (Ga/Ga + S) = 0.95 | | | | | | |

In case that the precursors configured to from component material in cationic complex systems such as AgGaS have more anions than cations (Comparative Examples 1 and 2), it may have a bond with the core other than the AgGaS composition to be obtained, and the composition such as In—Ga—S, Ag—In—Ga—S and Ag—In—S, or Ga—S, In—S and Ag—S may be obtained. Therefore, the wavelength and Full Width at Half Maximum are increased as a result.

Conversely, in case that cations are much more than anions (Comparative Examples 3 and 4), the cation exchange occurs with the prepared core, and the improvement of the optical characteristics is limited due to the relative increase in the thickness of the first shell and uneven growth of the core. Therefore, the improvement of the optical characteristics is limited.

However, a more excellent and homogeneous structure of the first shell is obtained when the amounts of precursors configured to form the first shell are uniform or the cations are less than the anions such as Examples 1 to 5. The result of the improvement in the optical characteristics as Ga increases is the result of the well-formed Ga shell, and is expressed as a result of an increase in the luminescence efficiency and a decrease in Full Width at Half Maximum.

In the configuration of the second shell which is not a complex system such as Examples 6 to 10, the amounts of precursors configured to form the second shell are uniform or the cations are less than the anions, it is more effective in forming a homogeneous second shell of GaS, so that the optical characteristics may be improved by suppressing interface defects between the first shell and the second shell rather than the formation of other compositions. By controlling the stoichiometry in the reaction adjacent to the core or the first shell, the first shell or the second shell, the second shell is effectively formed, thereby showing a decrease in Full Width at Half Maximum and an increase in the luminescence efficiency.

Through Examples 1 to 10 of AgInGaS/AgGaS/GaS quantum dots and Comparative Examples 1 to 4, it has been described that when the first shell has the molar ratio of Ga and Ag+Ga+S of 1:10 to 1:2 and the second shell has the molar ratio of Ga and Ga+S of 1:10 to 1:2, the wavelength and Full Width at Half Maximum of the quantum dot is reduced and the luminescence efficiency of the quantum dot is improved.

In the above-described Examples 1 to 10, AgInGaS/AgGaS/GaS quantum dots in which the Group I element is Ag, the Group III element is Ga, and the Group VI element is S, used in the first shell and the second shell, are representatively described. However, even if the Group I element included in the first shell is element other than Ag, the Group III element included in the first and second shells 14 and 16 is one of Al, In, and Tl other than Ga and the Group VI element included in the first and second shells 14 and 16 is one of Se and Te other than S, for the same reason, AgInGaS/first shell/second shell quantum dots in which the first shell has the molar ratio of Ga and Ag+Ga+S of 1:10 to 1:2 and the second shell has the molar ratio of Ga and Ga+S of 1:10 to 1:2, can reduce the wavelength and Full Width at Half Maximum and improve the luminescence efficiency.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention. Thus, the scope of the present invention is not limited to the embodiments shown, but is to be accorded the widest scope consistent with the claims. The scope of protection of the present invention should be construed based on the following claims, and all technical ideas within the scope of equivalents thereof should be construed as being included within the scope of the present invention.

### CROSS-REFERENCE TO RELATED APPLICATION

This application claims priority benefit from Korean Patent Application No. 10-2022-0154931, filed on Nov. 17, 2022, the entire contents of which are hereby expressly incorporated by reference for all purposes as if fully set forth herein.

1. A quantum dot comprising:
a core including silver (Ag), indium (In), gallium (Ga) and sulfur(S); and
a first shell on the core, the first shell including at least one Group I element, at least one Group III element and at least one Group VI element, wherein the first shell has a molar ratio of the Group III element and the Group I element+the Group III element+the Group VI element of 1:10 to 1:2.

2. The quantum dot of claim 1, wherein further comprising:
a second shell on the first shell, the second shell including at least one Group III element and at least one Group VI element, wherein the second shell has a molar ratio of the Group III element and the Group III element+the Group VI element of 1:10 to 1:2.

3. The quantum dot of claim 1, wherein the first shell has the molar ratio of the Group III element and the Group I element+the Group III element+the Group VI element of 3:10 to 1:2.

4. The quantum dot of claim 2, wherein the second shell has the molar ratio of the Group III element and the Group III element+the Group VI element of 3:10 to 1:2.

5. The quantum dot of claim 1, wherein the at least one Group I element included in the first shell includes one or more selected from Li, Na, K, Rb, Cs, Cu, Ag, and Au.

6. The quantum dot of claim 2, wherein the at least one Group III element included in the first shell and the second shell includes one or more selected from Al, Ga, In and Tl, and
the Group III element included in the first shell and the Group III element included in the second shell are the same of different.

7. The quantum dot of claim 2, wherein the at least one Group VI element included in the first shell and the second shell includes one or more selected from S, Se and Te, and
the Group VI element included in the first shell and the Group VI element included in the second shell are the same of different.

8. A method for manufacturing a quantum dot, the method comprising:
a core preparation step of preparing a core by injecting and reacting a silver precursor, an indium precursor, a gallium precursor, a sulfur precursor and a solvent in a first reactor; and
a first shell preparation step of preparing a first shell by injecting and reacting the prepared core in a first reactor containing at least one of a Group I precursor including a Group I element and a Group III precursor including a Group III element, and a Group VI precursor including a Group VI element, wherein the first shell has a molar ratio of the Group III element and the Group I element+the Group III element+the Group VI element of 1:10 to 1:2.

9. The method of claim 8, wherein further comprising:
a second shell preparation step of preparing the second shell by injecting and reacting the prepared core/first shell in a second reactor containing a Group III precursor including at least one Group III element and a Group VI precursor including at least one Group VI element, wherein the second shell has a molar ratio of the Group III element and the Group III element+the Group VI element of 1:10 to 1:2.

10. The method of claim 8, wherein the first shell has the molar ratio of the Group III element and the Group I element+the Group III element+the Group VI element of 3:10 to 1:2.

11. The method of claim 9, wherein the second shell has the molar ratio of the Group III element and the Group III element+the Group VI element of 3:10 to 1:2.

12. The method of claim 8, wherein the Group I element included in the first shell includes one or more selected from Li, Na, K, Rb, Cs, Cu, Ag, and Au.

13. The method of claim 9, wherein the at least one Group III element included in the first shell and the second shell includes one or more selected from Al, Ga, In and Tl, and
the Group III element included in the first shell and the Group III element included in the second shell are the same of different.

14. The method of claim 9, wherein the at least one Group VI element included in the first shell and the second shell includes one or more selected from S, Se and Te, and
the Group VI element included in the first shell and the Group VI element included in the second shell are the same of different.

15. An electronic device comprising:
a display device including a light emitting diode including a quantum dot; and
a controller driving the display device,
wherein the quantum dot comprising: a core including silver (Ag), indium (In), gallium (Ga) and sulfur(S), and a first shell on the core, the first shell including at least one Group I element, at least one Group III element and at least one Group VI element, wherein the first shell has a molar ratio of the Group III element and the Group I element+the Group III element+the Group VI element of 1:10 to 1:2.

16. The electronic device of claim 15, wherein the quantum dot further comprising:
a second shell on the first shell, the second shell including at least one Group III element and at least one Group VI element, wherein the second shell has a molar ratio of the Group III element and the Group III element+the Group VI element of 1:10 to 1:2.

17. The electronic device of claim 15, wherein the first shell has the molar ratio of the Group III element and the Group I element+the Group III element+the Group VI element of 3:10 to 1:2.

18. The electronic device of claim 16, wherein the second shell has the molar ratio of the Group III element and the Group III element+the Group VI element of 3:10 to 1:2.
